(19) United States
(12) Patent Application Publication
(10) Pub. No.: US 2005/0114807 A1
(43) Pub. Date: May 26, 2005

(54) Cross talk analysis methodology and solution

(76) Inventor: Frantisek Gasparik, Monument, CO (US)

Correspondence Address: LSI LOGIC CORPORATION, 1621 BARBER LANE, MS: D-106, MILPITAS, CA, 95035, US

(21) Appl. No.: 10/719,815

(22) Filed: Nov. 21, 2003

(51) Int. Cl. G06F 9/45; G01R 31/00

(52) U.S. Cl. 716/5; 324/500

(57) ABSTRACT

Disclosed is an analysis methodology and equivalent RLC circuits that accurately model the effects of packaging circuitry, bond wire circuitry and other sources of cross talk within an integrated-circuit signal transmission system.

### BACKGROUND OF THE INVENTION

a. Field of the Invention

The present invention generally pertains to integrated-circuit packaging and more particularly to analysis of the cross talk created in integrated-circuit packaging.

b. Description of the Background

As the frequency of integrated circuits increases to 1 GHz and greater, various problems, such as cross talk, arise in integrated circuit signal transmission systems. For example, plastic ball grid array (PBGA) packaging contains both bond wires and packaging wires that create cross talk problems. These problems increase as the number of wires used increases and as the frequency of operation increases. Cross talk between IC packages and bond wires causes energy to be injected into adjacent and relatively-adjacent conductors. The injected energy causes distortion of the signals in these adjacent and relatively-adjacent conductors.

Simulations have been performed in an attempt to identify the sources and effects of cross talk and eliminate them. However, these simulations have generally been ineffective. Simulations generally use ideal pulse shapes to simulate cross talk effects. In addition, modeling of the characteristics of PGBA packaging, and bond wires has not provided simulation results adequate to describe a signal source and its effects on physical circuits.

It would therefore be advantageous to provide an accurate analysis methodology for modeling cross talk effects in packaging and bond wire circuitry as well as other sources of cross talk in IC signal transmission systems, including integrated circuits themselves, to identify the source and effect of cross talk at high frequencies.

### SUMMARY OF THE INVENTION

The present invention overcomes the disadvantages and limitations of the prior art by providing an analysis methodology and equivalent RLC circuit models that accurately predict the effects of packaging circuitry, bond wire circuitry and any other sources of cross talk in an integrated-circuit signal transmission system, including integrated circuits themselves.

The present invention may therefore comprise a method of analyzing the effects of cross talk in a high frequency integrated circuit transmission system comprising: modeling traces in said high frequency integrated circuit transmission system with an equivalent resistance, equivalent capacitance, and equivalent inductance; calculating the inductance of said traces individually using an inductance matrix in which diagonal elements of said inductance matrix represent self-inductance of individual traces and non-diagonal elements of said inductance matrix represent mutual inductance between any two of said individual traces; calculating the capacitance of said traces individually using a capacitance matrix in which diagonal elements of said capacitance matrix represent total capacitance of individual traces and non-diagonal elements of said capacitance matrix represent capacitance between any two of said individual traces; calculating cross talk of said system created as a result of said inductance calculated by said inductance matrix and said capacitance calculated using said capacitance matrix.

The present invention may further comprise a method of analyzing the effects of cross talk in a circuit that includes a bond wire and a package comprising: modeling the bond wire with an equivalent bond wire resistance, equivalent bond wire capacitance, and equivalent bond wire inductance; modeling the package with an equivalent package resistance, equivalent package capacitance, and equivalent package inductance; calculating the inductance of individual traces of the bond wire and the package using an inductance matrix in which diagonal elements of the inductance matrix represent self-inductance of individual traces of the bond wire and the package and non-diagonal elements of the inductance matrix represent mutual inductance between any two of the individual traces of the bond wire and the package; calculating the capacitance of individual traces of the bond wire and the package using a capacitance matrix in which diagonal elements of the capacitance matrix represent total capacitance of individual traces of the bond wire and the package and non-diagonal elements of the capacitance matrix represent capacitance between any two of the individual traces of the bond wire and the package; calculating cross talk of the circuit created by the bond wire and the package as a result of the inductance calculated by the inductance matrix and the capacitance calculated using the capacitance matrix.

The present invention may further comprise an analysis system that analyzes cross talk created by bond wires and an integrated-circuit package made in a signal transmission system comprising: computer code that models said bond wire with an equivalent bond wire resistance, equivalent bond wire capacitance, and equivalent bond wire inductance; computer code that models said package with an equivalent package resistance, equivalent package capacitance, and equivalent package inductance; computer code that calculates the inductance of individual traces of said bond wire and said package using an inductance matrix in which diagonal elements of said inductance matrix represent self-inductance of individual traces of said bond wire and said package and non-diagonal elements of said inductance matrix represent mutual inductance between any two of said individual traces of said bond wire and said package; computer code that calculates the capacitance of individual traces of said bond wire and said package using a capacitance matrix in which diagonal elements of said capacitance matrix represents total capacitance of said individual traces of said bond wire and said package and non-diagonal elements of said capacitance matrix represent capacitance between any two of said individual traces of said bond wire and said package; computer code that calculates cross talk of said system created by said bond wire and said package as a result of said inductance calculated by said inductance matrix and said capacitance calculated using said capacitance matrix.

The advantages of the present invention are that effective modeling of equivalent circuits for PCB traces, packaging, bond wires and other IC transmission systems, including traces within the IC, allows the user to properly analyze these circuits and identify the source of problems created by cross talk effects so that a user may provide solutions to those cross talk problems.

### BRIEF DESCRIPTION OF THE DRAWINGS

In the drawings,

FIG. 1A is an illustration of a typical integrated circuit signal transmission system.

FIG. 1B is an illustration of an additional portion of a typical integrated circuit signal transmission system.

FIG. 1C is a schematic diagram of a circuit model for an integrated circuit signal transmission system.

FIG. 2 is a schematic diagram of an RLC equivalent circuit for sources of cross talk such as a packaging circuit, a bond wire circuit or other sources.

FIG. 3 is an illustration of a matrix showing inductance and mutual inductance for each of the conductors for packaging traces and bond wire conductors.

FIG. 4 is an illustration of a matrix showing capacitance between any two traces of the RLC circuit of FIG. 2 for each of the conductors for packaging traces and bond wire conductors or other conductors.

FIG. 5 is an example of a simulated circuit response at the input of the receiver for the circuit model of FIG. 1.

FIG. 6 is a simulated circuit response at the output of the receiver for the circuit model of FIG. 1.

FIG. 7 is a simulated circuit response at the output of the receiver for the circuit model of FIG. 1 after reducing cross talk.

### DETAILED DESCRIPTION OF THE INVENTION

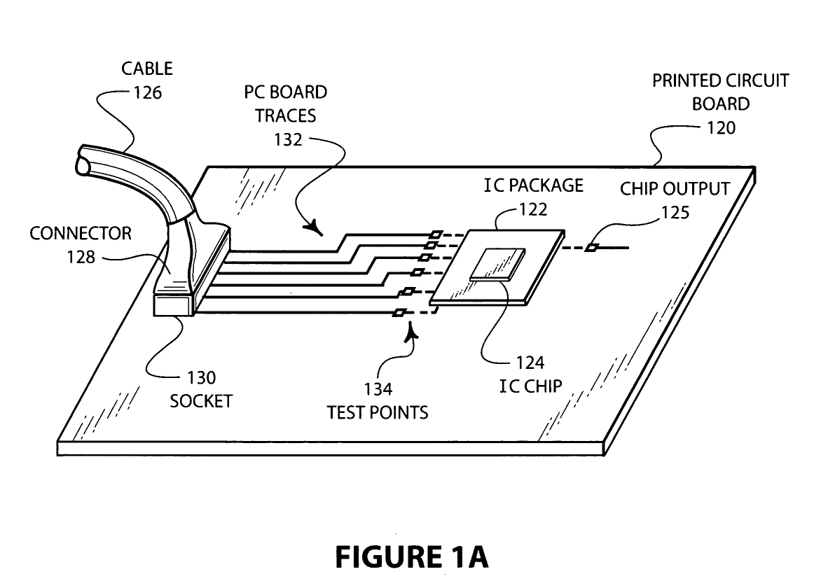

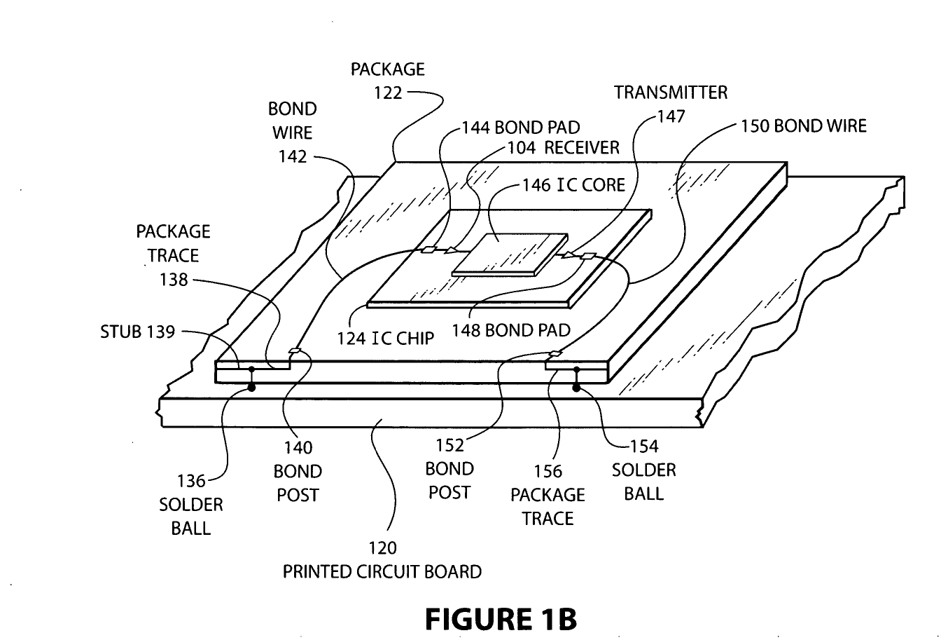

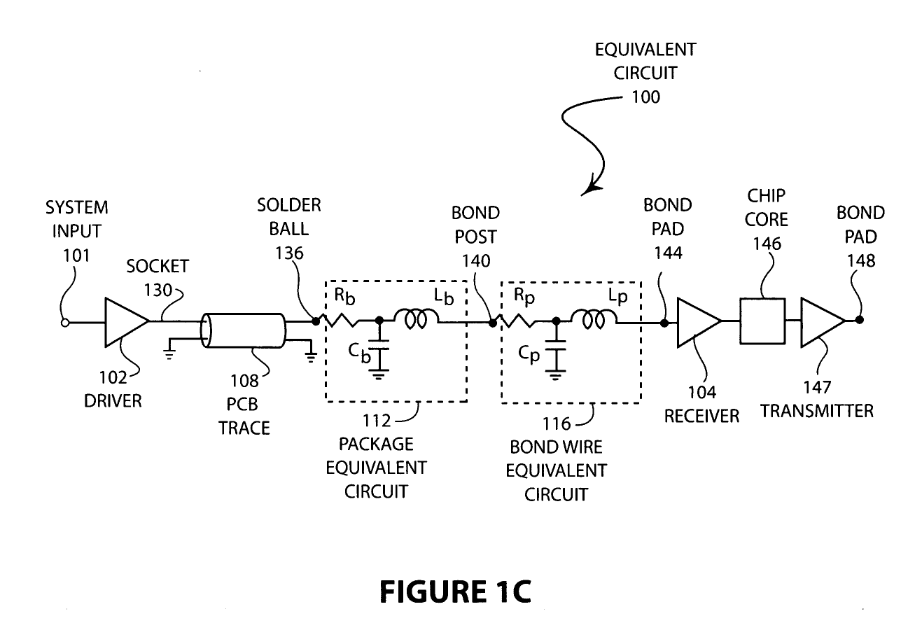

FIG. 1A is a schematic illustration of an integrated circuit high frequency transmission system. The system includes a cable 126 that is connected to a driver (not shown). The cable 126 is also coupled to a connector 128 that is inserted in a socket 130 on the printed circuit board 120. The socket 130 is connected to a series of printed circuit board traces 132. These printed circuit board traces 132 have accessible test points 134 for connecting an oscilloscope or other test device to check the signal waveforms. These test points 134 allow testing of the signal waveform prior to transmission to the integrated circuit package 122. Mounted on the integrated circuit package 122 is an integrated circuit chip 124 that receives the high frequency signals transmitted from the cable 126.

Frequently, cross talk can occur as a result of the routing of the PC board traces 132. More often, however, cross talk can occur from routing of traces in the IC package 122, bond wires that connect the IC chip 124 to the package 122 and in the IC itself. Bond wire and package circuitry are shown in more detail in FIG. 1B.

FIG. 1B discloses the package traces 138 and bond wires 142 in more detail. As shown in FIG. 1B, solder ball 136 connects the package 122 to the printed circuit board 120. Connected to the solder ball 136, is a package trace 138 that provides a connection to bond post 140. In addition, there is a stub 139 that extends to the edge of the package 122. A bond wire 142 is connected to the bond post 140 on the integrated circuit package 122. The bond wire is also connected to a bond pad 144 on the integrated circuit chip 124. The bond pad 144 provides an internal connection to the circuitry of the integrated circuit chip 124. For example, the bond pad 144 may be connected to a receiver 104, which in turn is connected to the core of the integrated circuit 146. The IC core 146 is connected to a transmitter, which is, in turn, connected to a bond pad 148. Bond pad 148 is connected to a bond wire 150, which in turn is connected to bond post 152 on the package 122. The bond post 152 is connected to a package trace 156, which, in turn, is connected to a solder ball 154. Solder ball 154 connects to PC board traces to an output test pad 125, shown in FIG. 1A.

Typically it is not possible to access the internal bond pad or the IC core 146 to determine signal shape or other problems with the high frequency signals. Rather, access may only be provided at the test points 134 and the chip output test point 125, shown in FIG. 1A. Hence, there is no way to accurately measure the effects of cross talk that are created by the package traces 138, 156 and the various other package traces not shown, as well as the bond wires 142, 150 and other bond wires that are not shown.

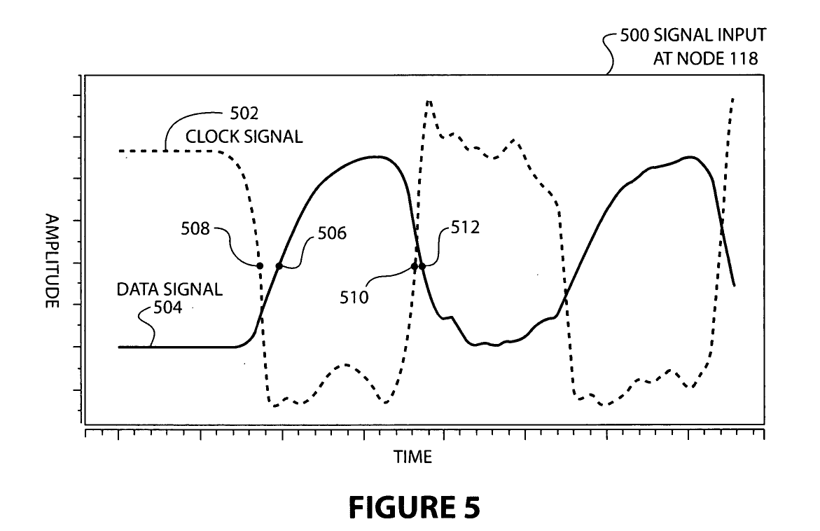

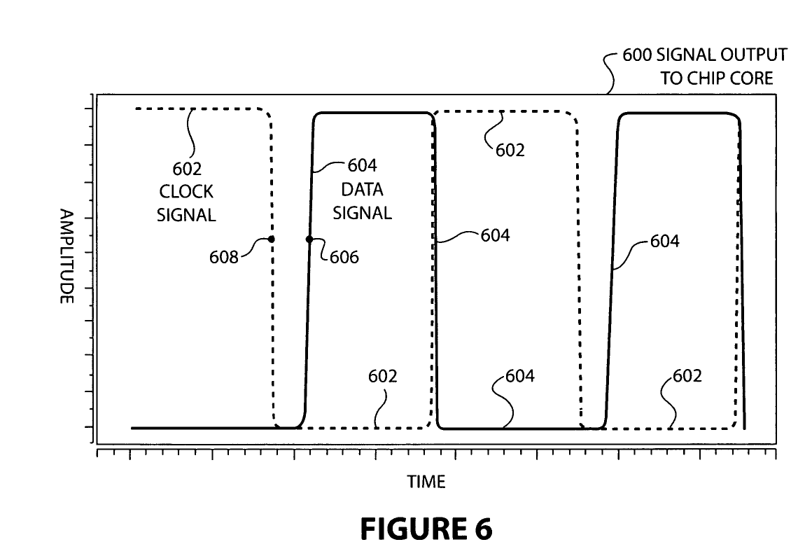

FIG. 1C is a schematic diagram of the equivalent circuit 100 of the high frequency transmission system illustrated in FIGS. 1A and 1B. The driver 102 may be an external driver such as a PCI-X, SCSI, Fiber Channel or other type of driver. Driver 102 transmits signals to the printed circuit board 120, via cable 126, connector 128, or optical link, etc. to a connector 128 on the PC board 120, such as socket 130. Socket 130 is connected to printed circuit board traces 132 that, in turn, are connected to package 122 at solder ball 136. The package has its own equivalent circuit 112, represented by the resistance R_{b}, capacitance C_{b} and inductance L_{b} in FIG. 1C. The package is connected directly to the bond wire 142 at bond post 140. The bond wire 142 also has its own equivalent circuit 116, represented by the resistance Rₚ, capacitance Cₚ and inductance Lₚ in FIG. 1C. The bond wire 142 is then connected to the receiver 104 at bond pad 144 on the chip. The receiver 104 is connected to chip core 146, which, in turn, is connected to transmitter 147. Transmitter 147 is connected to bond pad 148. Bond pad 148 is eventually connected to chip output 125 (FIG. 1A), which is a contact point for various electronic instruments, such as an oscilloscope, that can measure and display the output signal. As shown in FIG. 1C, the printed circuit board traces 108 are not modeled with an equivalent circuit. Normally, the printed circuit board traces are well laid out and balanced so that cross talk effects are not a problem. However, since the package traces and bond wires are numerous and are laid out very closely and in parallel, cross talk can be a problem. Hence, the package equivalent circuit 112 and the bond wire equivalent circuit 116 provide a model for analyzing potential cross talk effects of these conductors. The results of cross talk from the package traces and bond wire conductors, creates a distorted signal at the bond pad 144 (FIG. 1C), as shown in FIG. 5. Receiver 104 and transmitter 147 constitute high gain amplifiers that resolve the distortion, as shown in FIG. 5, to create the signals illustrated in FIG. 6. By resolving the distortion created by the distortion of the signals using receiver 104, an accurate analysis of the results of cross talk from the packaging and other transmission sources can be made without access to a non-accessible internal node of the system. Such an analysis allows verification of steps taken to correct cross talk effects in the system.

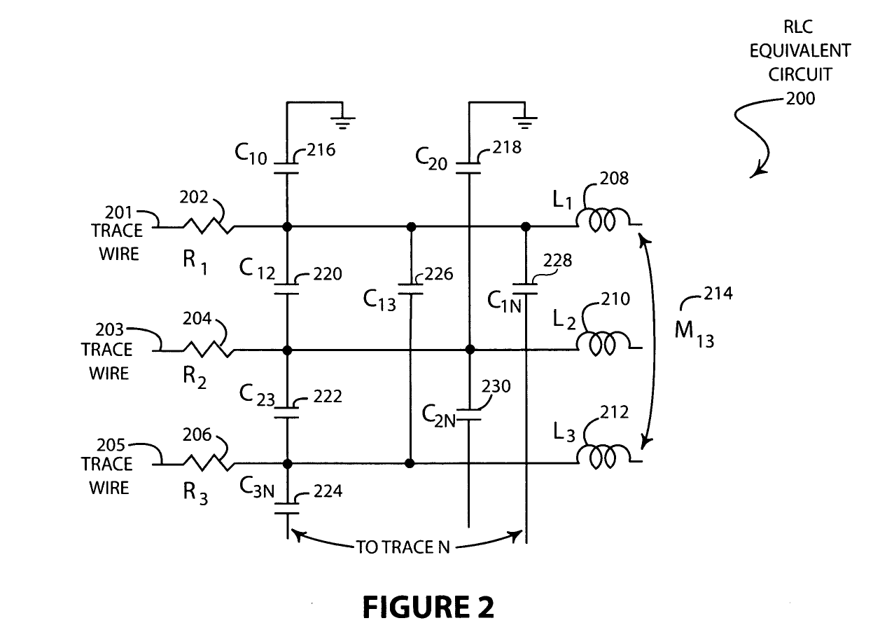

FIG. 2 is an equivalent RLC circuit 200 representing the effects of cross talk in trace wires, such as bond wires, package wires, etc. The signal through trace wire 201 is affected by the trace wire intrinsic resistance (R₁) 202, intrinsic inductance (L₁) 208 and intrinsic capacitance (C₁₀) 216 with respect to AC ground. In addition, the signal through trace wire 201 is affected by the cross talk generated by the signal through trace wire 203 [(as represented by the capacitance (C₁₂) 220 and mutual inductance (M₁₂) (not shown)], through trace wire 205 [as represented by the capacitance (C₁₃) 226 and mutual inductance (M₁₃) 214], and through all N trace wires in the system [as represented by the capacitance (C_{IN}) 228 and mutual inductance M_{IN} (not shown)].

In like manner, the signal through trace wire 203 is affected by the trace wire intrinsic resistance (R₂) 204, intrinsic inductance (L₂) 210 and intrinsic capacitance (C₂₀) 218 with respect to AC ground. In addition, the signal through trace wire 203 is affected by the cross talk generated by the signal through trace wire 201 (as represented by the capacitance (C₁₂) 220 and mutual inductance (M₁₂) [not shown]), through trace wire 205 (as represented by the capacitance (C₂₃) 222 and mutual inductance (M₂₃) [not shown]), and through all N trace wires in the system (as represented by the capacitance (C_{2N}) 230 and mutual inductance M_{2N} [not shown]).

Further, the signal through trace wire 205 is affected by its intrinsic resistance (R₃) 206, intrinsic inductance (L₃) 212 and intrinsic capacitance (C₃₀) [not shown] with respect to AC ground. In addition, the signal through trace wire 205 is affected by the cross talk generated by the signal through trace wire 201 [as represented by the capacitance (C₁₃) 226 and mutual inductance (M₁₃) 214], through trace wire 203 [as represented by the capacitance (C₂₃) 222 and mutual inductance (M₂₃) (not shown)], and through all N trace wires in the system [as represented by the capacitance (C₃N) 224 and mutual inductance (M₃N) (not shown)].

The signal through each of the N trace wires in the system is affected by cross talk from all other trace wires in the system. The cross talk between wires increases as the frequency of signals in the system increases, since inductance and capacitance values are proportional to frequency. The cross talk between wires also increases as wires are placed closer together because the electromagnetic effects between wires are inversely proportional to the distance between wires.

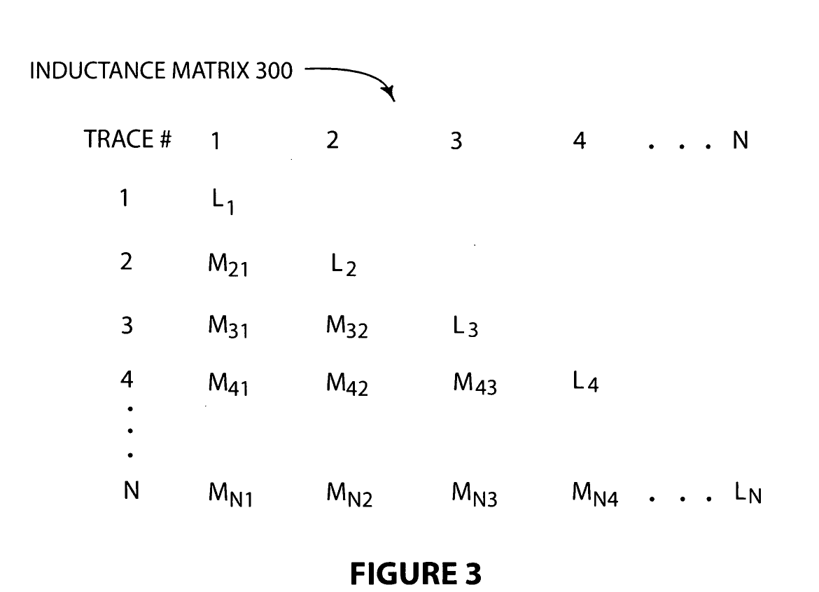

The inductance effects felt by each trace wire in a system can be organized in a matrix, as in FIG. 3. The long diagonal of the inductance matrix 300 from top left to bottom right contains the intrinsic inductance L₁, L₂, L₃, L₄, . . . L_{N} of each of the N trace wires. The non-diagonal matrix elements contain the mutual inductance of any combination of two trace wires in the system, i.e., M₂₁ is the mutual inductance between trace wire 201 and trace wire 203. In a passive system, the matrix is symmetrical with respect to the long diagonal; i.e., M₁₂ (not shown) is equal to M₂₁, etc., reducing the effort needed to complete the matrix.

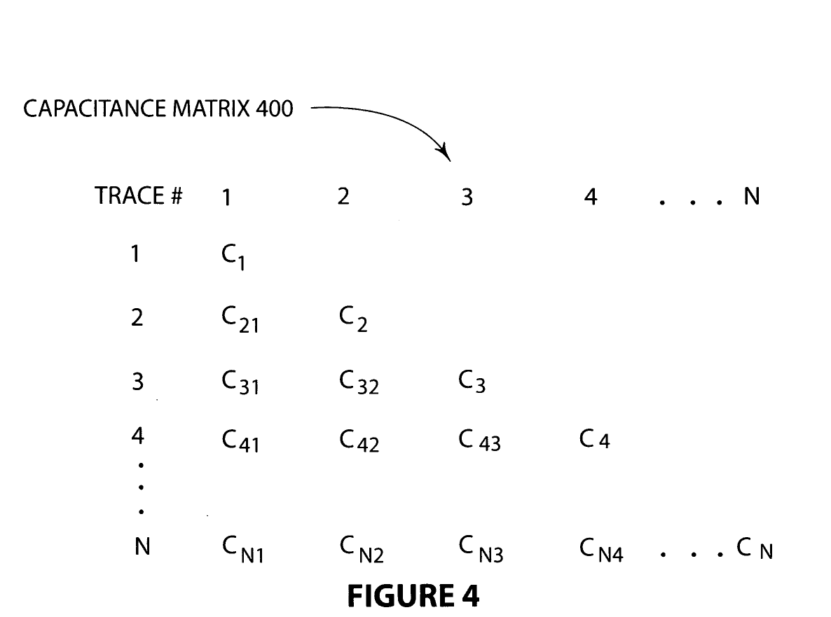

In like manner to FIG. 3, the capacitance effects felt by each wire or trace in a system can be organized in a matrix, as in FIG. 4. The long diagonal of the capacitance matrix 400 from top left to bottom right contains the total capacitance C₁, C₂, C₃, C₄, . . . C_{N} of each of the N trace wires, where C₁=C₂₁+C₃₁+C₄₁+ . . . +C_{N1}. The non-diagonal matrix elements contain the capacitance of any combination of two trace wires in the system, i.e., C₂₁ is the capacitance between trace wire 201 and trace wire 203. In a passive system, the matrix is symmetrical with respect to the long diagonal; i.e., C₁₂ (not shown) is equal to C₂₁, etc., reducing the effort needed to complete the matrix.

FIG. 5 is a graph of the clock signal 502 and data signal 504 at bond pad 144 illustrating that the data signal 604 violates the hold time for the signal. The effects of cross talk create the distortion of the signals shown in FIG. 5. The receiver 104 resolves the distortion of FIG. 5, as shown in FIG. 6. However, the effects of cross talk cause the data signal to have a slow rise time and a faster fall time, as shown in FIG. 5. The delay at point 506, reaching the value of point 508, is caused by cross talk. The points 510 and 512 have a different delay. The delay between point 512 and point 510 is much smaller. Since integrated-circuit systems require strict limits on the setup and hold times for clock and data signals to ensure proper performance, cross talk that lengthens the setup time and shortens the hold time of a data signal negatively impacts system performance.

As pointed out above, receiver 104 (FIG. 1) resolves the distortion of the signals illustrated in FIG. 5, but creates a data signal 606 that violates hold time. These signals that violate hold time are transmitted to the chip core 146. FIG. 6 is a graph 600 showing the clock signal 602 and data signal 604 that are transmitted to the chip core 146. The clock signal 602 and data signal 604 both have squarer pulse shapes. However, the signal improvements caused by the receiver 104 do not include elimination of the effects of cross talk. In particular, since the data signal 506 (FIG. 5) does not rise at the same speed it falls, correction of the data signal 506 (FIG. 5) to the corrected data signal 604 (FIG. 6) creates a lag in the positive data pulse 604. In other words, as shown in FIG. 6, the time when the data signal 604 goes positive is considerably later than the equivalent time when the clock signal goes negative. The delay of point 606 reaching the mid-value point 608 is caused by cross talk, which is not corrected by the receiver 104. Stated differently, since the data signal falls at a faster speed, the difference between the delays that exist between the clock and data signals is not the same for the rising and falling pulses, and the data signal violates hold time. Thus in FIG. 1, even after the receiver 104 has processed the signal, the input to the chip core 146 still includes the effects of cross talk. These effects can seriously affect the logic of the chip circuit.

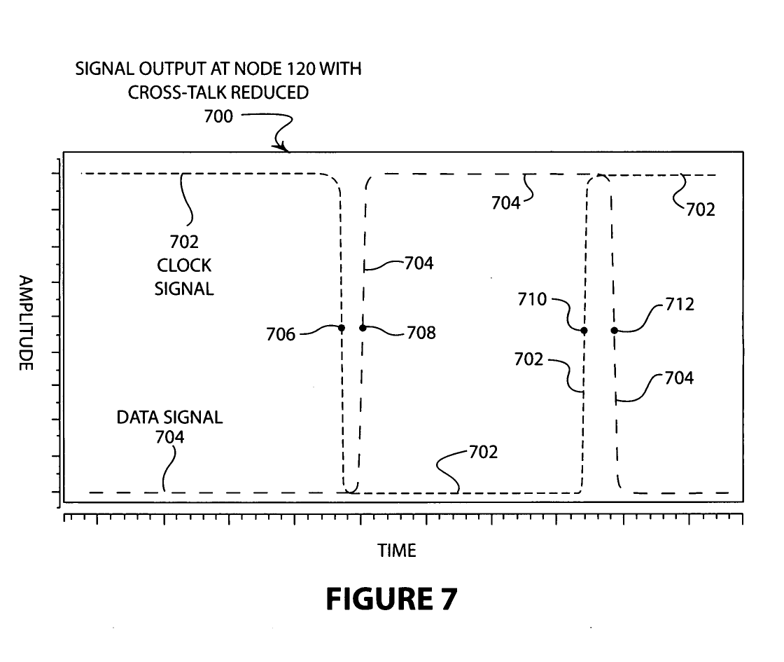

FIG. 7 is a graph 700 of the chip core output 120 after cross talk is reduced at the receiver input 144. As can be seen from FIG. 7, the amount of delay of the data signal 704 from the clock signal 702 is equal at both the rise time and fall time. The mid-point of both the clock signal 702 and the data signal 704 indicated by points 706, 708, respectively, illustrates a delay that is equal to the delay between points 710, 712. Thus, the system cross talk that lengthened the setup time of the data signal in FIG. 5 and FIG. 6, and shortened the hold time of the data signal in FIG. 5 and FIG. 6, has been reduced in FIG. 7, so that the hold time is not violated.

The present invention therefore provides a method of analyzing cross talk within an integrated-circuit system and minimizing cross talk in certain circuits. These techniques can be used to identify problems so that steps can be taken to identify the source of cross talk problems and eliminate them.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A method of analyzing the effects of cross talk in a circuit that includes a bond wire and a package comprising:
modeling said bond wire with an equivalent bond wire resistance, equivalent bond wire capacitance, and equivalent bond wire inductance;
modeling said package with an equivalent package resistance, equivalent package capacitance, and equivalent package inductance;
calculating the inductance of individual traces of said bond wire and said package using an inductance matrix in which diagonal elements of said inductance matrix represent self-inductance of individual traces of said bond wire and said package and non-diagonal elements of said inductance matrix represent mutual inductance between any two of said individual traces of said bond wire and said package;
calculating the capacitance of individual traces of said bond wire and said package using a capacitance matrix in which diagonal elements of said capacitance matrix represent total capacitance of individual traces of said bond wire and said package and non-diagonal elements of said capacitance matrix represent capacitance between any two of said individual traces of said bond wire and said package;
calculating cross talk of said circuit created by said bond wire and said package as a result of said inductance calculated by said inductance matrix and said capacitance calculated using said capacitance matrix.

2. A method of analyzing the effects of cross talk in a high frequency integrated circuit transmission system comprising:
modeling traces in said high frequency integrated circuit transmission system with an equivalent resistance, equivalent capacitance, and equivalent inductance;
calculating the inductance of said traces individually using an inductance matrix in which diagonal elements of said inductance matrix represent self-inductance of individual traces and non-diagonal elements of said inductance matrix represent mutual inductance between any two of said individual traces;
calculating the capacitance of said traces individually using a capacitance matrix in which diagonal elements of said capacitance matrix represent total capacitance of individual traces and non-diagonal elements of said capacitance matrix represent capacitance between any two of said individual traces;
calculating cross talk of said system created as a result of said inductance calculated by said inductance matrix and said capacitance calculated using said capacitance matrix.

3. An analysis system that analyzes cross talk created by bond wires and an integrated-circuit package made in a signal transmission system comprising:
computer code that models said bond wire with an equivalent bond wire resistance, equivalent bond wire capacitance, and equivalent bond wire inductance;
computer code that models said package with an equivalent package resistance, equivalent package capacitance, and equivalent package inductance;
computer code that calculates the inductance of individual traces of said bond wire and said package using an inductance matrix in which diagonal elements of said inductance matrix represent self-inductance of individual traces of said bond wire and said package and non-diagonal elements of said inductance matrix represent mutual inductance between any two of said individual traces of said bond wire and said package;
computer code that calculates the capacitance of individual traces of said bond wire and said package using a capacitance matrix in which diagonal elements of said capacitance matrix represents total capacitance of said individual traces of said bond wire and said package and non-diagonal elements of said capacitance matrix represent capacitance between any two of said individual traces of said bond wire and said package;
computer code that calculates cross talk of said system created by said bond wire and said package as a result of said inductance calculated by said inductance matrix and said capacitance calculated using said capacitance matrix.

4. An analysis system that analyzes cross talk created by bond wires and an integrated-circuit package in a signal transmission system comprising:
means for modeling said bond wire with an equivalent bond wire resistance, equivalent bond wire capacitance, and equivalent bond wire inductance;
means for modeling said package with an equivalent package resistance, equivalent package capacitance, and equivalent package inductance;
means for calculating the inductance of individual traces of said bond wire and said package using an inductance matrix in which diagonal elements of said inductance matrix represent self-inductance of individual traces of said bond wire and said package and non-diagonal elements of said inductance matrix represent mutual inductance between any two of said individual traces of said bond wire and said package;
means for calculating the capacitance of individual traces of said bond wire and said package using a capacitance matrix in which diagonal elements of said capacitance matrix represents total capacitance of said individual traces of said bond wire and said package and non-diagonal elements of said capacitance matrix represent capacitance between any two of said individual traces of said bond wire and said package;
means for calculating cross talk of said system created by said bond wire and said package as a result of said inductance calculated by said inductance matrix and said capacitance calculated using said capacitance matrix.
